(19) United States
(12) Patent Application Publication
(10) Pub. No.: US 2008/0143912 A1
(43) Pub. Date: Jun. 19, 2008

(54) THIN FILM TRANSISTOR SUBSTRATE AND METHOD OF MANUFACTURING THE SAME

(76) Inventor: Dong-Gyu Kim, Yongin-si (KR)

Correspondence Address: F. CHAU & ASSOCIATES, LLC, 130 WOODBURY ROAD, WOODBURY, NY, 11797, US

(21) Appl. No.: 11/953,466

(22) Filed: Dec. 10, 2007

(30) Foreign Application Priority Data
Dec. 18, 2006 (KR) 10-2006-0129470

(51) Int. Cl. G02F 1/1368; H01L 21/71

(52) U.S. Cl. 349/48; 438/34

(57) ABSTRACT

A thin film transistor (TFT) substrate having an increased aperture ratio and a simple configuration. The TFT substrate includes a first gate line, a second gate line, and a data line, a first sub-pixel electrode and a second sub-pixel electrode. A first thin film transistor has three terminals connected to the first gate line, the data line, and the first sub-pixel electrode, respectively. A second thin film transistor has three terminals connected to the first gate line, the data line, and the second sub-pixel electrode, respectively. A coupling electrode overlaps the second sub-pixel electrode with a passivation layer interposed therebetween. A third thin film transistor has three terminals connected to the second gate line, the second sub-pixel electrode, and the coupling electrode, respectively.

### CROSS REFERENCE TO RELATED APPLICATION

This application claims priority to Korean Patent Application No. 10-2006-0129470 filed on Dec. 18, 2006 in the Korean Intellectual Property Office, the disclosure of which is herein incorporated by reference in its entirety.

### BACKGROUND OF THE INVENTION

1. Technical Field

The present invention relates to a thin film transistor (TFT) substrate and, more particularly, to a TFT substrate and a method of manufacturing the same.

2. Discussion of the Related Art

A liquid crystal display (LCD) displays an image such that respective liquid crystal cells arranged in a matrix formed on an LCD panel adjust light transmittance according to video signals. Such LCDs are equipped with wide-viewing angle technology to overcome narrow viewing angle and provide added clarity when viewing the LCD from a side, i.e. at a narrow viewing angle.

As a representative wide viewing angle technology for LCDs, a vertical alignment (VA) mode is used. In the VA mode, liquid crystal molecules having a negative dielectric anisotropy are vertically aligned and driven perpendicularly to the direction of an electric field, thus controlling the light transmittance. Such VA modes are classified into a multi-domain vertical alignment (MVA) mode, a patterned-ITO VA (PVA) mode, and an S-patterned-ITO VA (S-PVA) mode.

The MVA mode is a VA mode using projections. In particular, projections are formed on upper and lower substrates, in which liquid crystal molecules are arranged symmetrically to the projections to be pre-tilted. If a voltage is applied thereto, the liquid crystal molecules are driven in the pre-tilted direction to form a multi-domain.

The PVA mode is a VA mode using a slit pattern. In particular, slits are provided to common and pixel electrodes on upper and lower substrates to generate a fringe electric field. Liquid crystal molecules are driven symmetrically to the slit to form a multi-domain.

In the S-PVA mode, one pixel is divided into high and low gray scale sub-pixels representing data according to different gamma curves. Each of the sub-pixels is independently driven by a high gray scale thin film transistor.

Typical driving methods in the S-PVA mode include a one gate line and two data lines (1G-2D) method, a capacitor swing method, and a coupling capacitor method.

However, the 1G-2D method using two data lines has a reduced aperture ratio and an increased manufacturing cost of a data driver. In the capacitor swing method, resistors and capacitors require high power consumption and it becomes difficult to drive the LCD for higher definition. Also, in the coupling capacitor method, since a voltage difference between two pixels is small at a low gray scale level, a low visibility results and transmittance is decreased.

### SUMMARY OF THE INVENTION

An aspect the present invention provides a thin film transistor substrate including an additional thin film transistor (TFT), a storage electrode, and a coupling electrode. A relatively large aperture ratio may be provided with a simple configuration.

An exemplary embodiment of the present invention provides a thin film transistor substrate including a first gate line, a second gate line, and a data line. A first sub-pixel electrode and a second sub-pixel electrode are also provided. A first thin film transistor has three terminals connected to the first gate line, the data line, and the first sub-pixel electrode, respectively. A second thin film transistor has three terminals connected to the first gate line, the data line, and the second sub-pixel electrode, respectively. A coupling electrode is formed overlapping the second sub-pixel electrode with a passivation layer interposed therebetween. A third thin film transistor has three terminals connected to the second gate line, the second sub-pixel electrode, and the coupling electrode, respectively.

The passivation layer includes an inorganic passivation layer formed of an inorganic material and an organic passivation layer formed of an organic material on the inorganic passivation layer.

The third thin film transistor includes a gate electrode connected to the second gate line, a source electrode connected to the first sub-pixel electrode, a drain electrode formed acing the source electrode, and a semiconductor layer connected to the source electrode and the drain electrode.

The third thin film transistor is formed on the second gate line.

The first and second sub-pixel electrodes are formed in a chevron shape.

The area of the first sub-pixel electrode is greater than that of the second sub-pixel electrode.

The area ratio between the second sub-pixel electrode and the first sub-pixel electrode is 1:2.

The thin film transistor substrate of an exemplary embodiment of the present invention further includes a first storage line formed overlapping the first and second sub-pixel electrodes.

The thin film transistor substrate of an exemplary embodiment of the present invention further includes a first storage capacitor formed overlapping the first storage line and the first sub-pixel electrode with the inorganic passivation layer interposed therebetween. A second storage capacitor is formed overlapping the first storage line and the second sub-pixel electrode with the inorganic passivation layer interposed therebetween.

The thin film transistor substrate of an exemplary embodiment of the present invention further includes a second storage line formed overlapping the coupling electrode.

The thin film transistor substrate of an exemplary embodiment of the present invention further includes a storage electrode formed overlapping the coupling electrode with a gate insulating layer interposed therebetween.

A source electrode of the first thin film transistor is formed partially overlapping a source electrode of the second thin film transistor.

Another exemplary embodiment of the present invention provides a method of manufacturing a thin film transistor substrate. The method includes forming a gate metal pattern including a gate line, a gate electrode, and a storage line on a substrate. A gate insulating layer and a semiconductor pattern are formed on the gate metal pattern. A data metal pattern including a data line, a source electrode, and a drain electrode are formed on the gate insulating layer on which the semiconductor pattern is formed. A passivation layer is formed on the gate insulating layer and the data metal pattern. Contact holes exposing the gate metal pattern and the data metal pattern are formed by removing the passivation layer, and capacitor recesses are formed by removing a portion of the passivation layer. First and second sub-pixel electrodes are formed on the passivation layer, the contact holes, and the capacitor recesses.

The process of forming the passivation layer includes forming an inorganic passivation layer formed of an inorganic material on the gate insulating layer and the data metal pattern. An organic passivation layer is formed of an organic material on the inorganic passivation layer.

The process of forming the contact holes and the capacitor recesses includes forming a photoresist pattern, including an open area from which the photoresist pattern is removed and an intermediate area from which a portion of the photoresist pattern is removed, on the organic passivation layer. The contact holes are formed by removing the organic and inorganic passivation layers by the open area of the photoresist pattern. The photoresist pattern of an exposed area of the photoresist pattern is removed. The capacitor recesses is formed by removing the organic passivation layer by the exposed area of the photoresist pattern. The photoresist pattern is removed.

The process of forming the contact holes and the capacitor recesses uses a slit mask.

The process of forming the contact holes and the capacitor recesses uses a half-tone mask.

A further exemplary embodiment of the present invention provides a thin film transistor substrate including a first gate line, a second gate line, and a data line. A first sub-pixel electrode and a second sub-pixel electrode are also included. A first thin film transistor has three terminals connected to the first gate line, the data line, and the first sub-pixel electrode, respectively. A second thin film transistor has three terminals connected to the first gate line, the data line, and the second sub-pixel electrode, respectively. A passivation layer covers the data line, the first and second thin film transistors, and a third thin film transistor. A color filter is formed on the passivation layer. A coupling electrode is formed overlapping the second sub-pixel electrode with the passivation layer interposed therebetween. The third thin film transistor has three terminals connected to the second gate line, the second sub-pixel electrode, and the coupling electrode, respectively.

The passivation layer is an inorganic passivation layer formed of an inorganic material.

The third thin film transistor includes a gate electrode connected to the second gate line, a source electrode connected to the first sub-pixel electrode, a drain electrode formed to face the source electrode, and a semiconductor layer connected to the source and drain electrodes.

The third thin film transistor is formed on the second gate line.

The first and second sub-pixel electrodes are formed in a chevron shape.

The area of the first sub-pixel electrode is greater than that of the second sub-pixel electrode.

The area ratio between the second sub-pixel electrode and the first sub-pixel electrode is 1:2.

The thin film transistor substrate of an exemplary embodiment of the present invention further includes a first storage line formed overlapping the first and second sub-pixel electrodes.

The thin film transistor substrate of the present invention further includes a first storage capacitor formed overlapping the first storage line and the first sub-pixel electrode with the inorganic passivation layer interposed therebetween. A second storage capacitor is formed overlapping the first storage line and the second sub-pixel electrode with the inorganic passivation layer interposed therebetween.

The thin film transistor substrate according to an exemplary embodiment of the present invention further includes a second storage line formed overlapping the coupling electrode.

The thin film transistor substrate according to an exemplary embodiment of the present invention further includes a storage electrode formed overlapping the coupling electrode with a gate insulating layer interposed therebetween.

A source electrode of the first thin film transistor is formed partially overlapping a source electrode of the second thin film transistor in part.

It is to be understood that both the foregoing general description and the following detailed description of the present invention are exemplary and explanatory.

### BRIEF DESCRIPTION OF THE DRAWINGS

Exemplary embodiments of the present invention will be understood in more detail from the following descriptions taken in conjunction with the accompanying drawings. In the drawings:

FIG. 1 is a plan view of a TFT substrate according to an exemplary embodiment of the present invention;

FIGS. 2A to 2C are cross-sectional views of sub-pixels on the TFT substrate taken along lines I-I′, II-II′ and III-III′, respectively, in FIG. 1;

FIG. 3 is a plan view of a TFT substrate according to an exemplary embodiment of the present invention;

FIG. 4 is a plan view of a TFT substrate according to an exemplary embodiment of the present invention;

FIG. 5 is a plan view of a TFT substrate according to an exemplary embodiment of the present invention;

FIG. 6 is a diagram showing an equivalent circuit of the sub-pixel on the TFT substrate according to an exemplary embodiment of the present invention;

FIG. 7 is a diagram illustrating the operation of the sub-pixel on the TFT substrate according to an exemplary embodiment of the present invention;

FIGS. 8A and 8B to 8D are a plan view and cross-sectional views, respectively, illustrating a mask process in a method of manufacturing a TFT substrate according to an exemplary embodiment of the present invention;

FIGS. 9A and 9B to 9D are a plan view and cross-sectional views, respectively, illustrating a mask process in the method of manufacturing the TFT substrate according to an exemplary embodiment of the present invention;

FIGS. 10A and 10B to 10D are a plan view and cross-sectional views, respectively, illustrating a mask process in the method of manufacturing the TFT substrate according to an exemplary embodiment of the present invention;

FIGS. 11A to 11C are cross-sectional views illustrating a process of forming a passivation layer in a method of manufacturing the TFT substrate according to an exemplary embodiment of the present invention;

FIGS. 12A to 12L are cross-sectional views illustrating processes of forming contact holes and capacitor recesses in a method of manufacturing the TFT substrate according to an exemplary embodiment of the present invention;

FIGS. 13A and 13B to 13D are a plan view and cross-sectional views, respectively, illustrating a mask process in a method of manufacturing the TFT substrate according to an exemplary embodiment of the present invention;

FIG. 14 is a plan view of a TFT substrate according to an exemplary embodiment of the present invention; and

FIGS. 15A to 15C are cross-sectional views of the TFT substrate according to an exemplary embodiment of the present invention.

### DETAILED DESCRIPTION OF EXEMPLARY EMBODIMENTS

Reference will now be made in detail to exemplary embodiments of the present invention, examples of which are illustrated in the accompanying drawings. The same reference numbers may be used throughout the drawings to refer to the same or like parts.

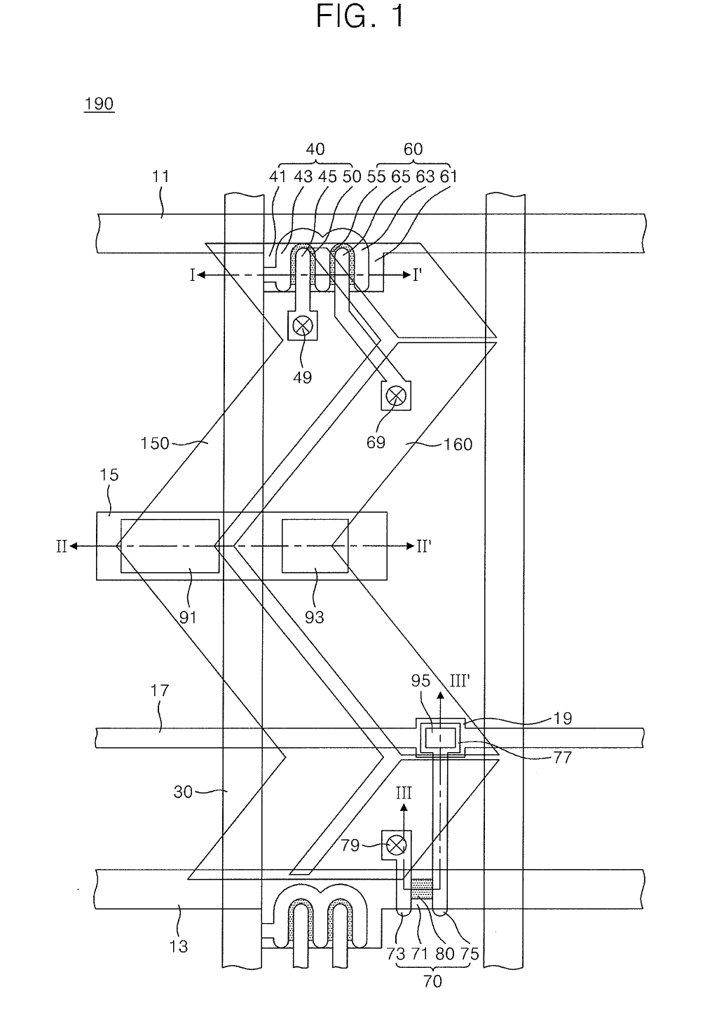

Hereinafter, exemplary embodiments of the present invention will be described in detail with reference to FIGS. 1 to 15C.

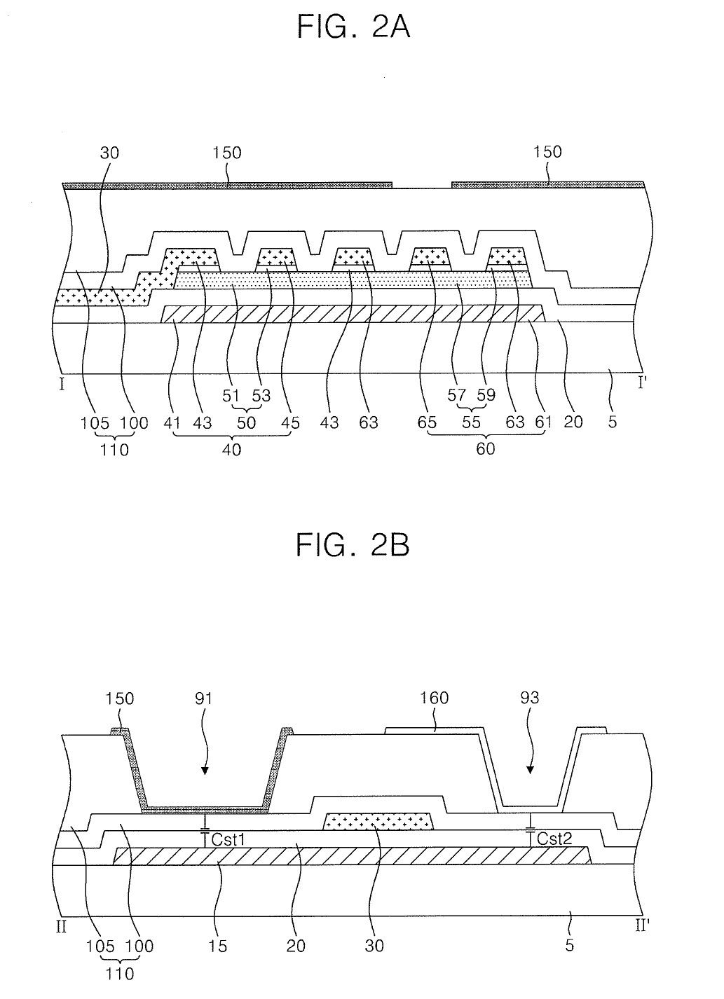

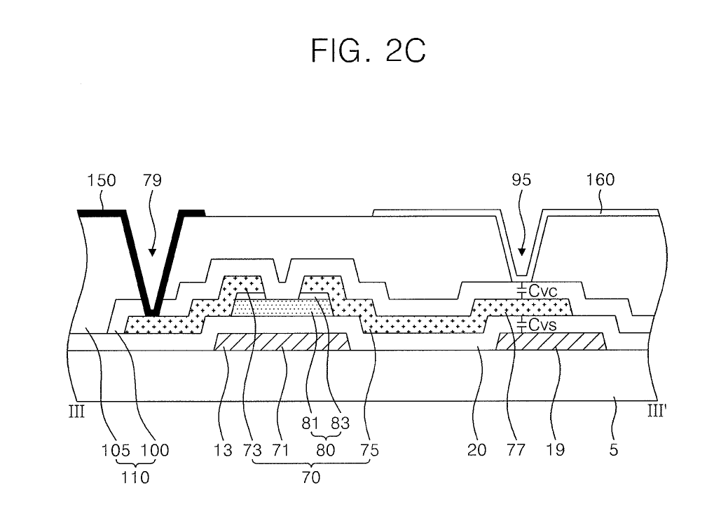

Referring to FIGS. 1, 2A, 2B and 2C, a sub-pixel of a TFT substrate 190 includes first and second gate lines 11 and 13, a gate insulating layer 20, a data line 30, first to third TFTs 40, 60 and 70, first and second storage lines 15 and 17, a passivation layer 110, and first and second sub-pixel electrodes 150 and 160. The sub-pixel on the TFT substrate is divided into a high gray scale area and a low gray scale area for the improvement of visibility.

The TFT substrate 190 includes the first and second gate lines 11 and 13 and the data line 30 to drive one sub-pixel. The first and second gate lines 11 and 13 are formed parallel to each other on a substrate 5. The first gate line 11 is connected to gate electrodes 41 and 61 of the first and second TFTs 40 and 60, respectively. The second gate line 13 is connected to a gate electrode 71 of the third TFT 70. The first and second gate lines 11 and 13 supply gate signals to the gate electrodes 41, 61 and 71 of the first to third TFTs 40, 60 and 70, respectively.

The storage lines are formed parallel to the gate lines 11 and 13 on the substrate 5. The storage lines include a first storage line 15 passing through a central part of each sub-pixel in a short axis direction to intersect the data line 30, and a second storage line 17 formed to intersect a drain electrode 75 of the third TFT 70.

The gate insulating layer 20 insulates a gate pattern including the first and second gate lines 11 and 13 and the first to third gate electrodes 41, 61 and 71 from a data pattern including first to third source electrodes 43, 63 and 73 and first to third drain electrodes 45, 65 and 75.

The data line 30 supplies a pixel voltage signal to each of the first to third source electrodes 43, 63 and 73 of the first to third TFTs 40, 60 and 70. The data line 30 is formed to intersect the first and second gate lines 11 and 13 with the gate insulating layer 20 interposed therebetween.

The first and second TFTs 40 and 60 respond to a gate signal of the first gate line 11 and the third TFT 70 responds to a gate signal of the second gate line 13 so that the pixel voltage signal from the data line 30 is charged to the first and second sub-pixel electrodes 150 and 160. The first TFT 40 is connected to the first sub-pixel electrode 150 to drive the low gray scale area, and the second and third TFTs 60 and 70 are connected to the second sub-pixel electrode 160 to drive the high gray scale area. The first and second TFTs 40 and 60 include the first and second gate electrodes 41 and 61, formed to protrude to the first gate line 11, and the first and second source electrodes 43 and 63, formed to surround a portion of the first and second drain electrodes 45 and 65, respectively. The first and second source electrodes 43 and 63 are formed overlapping each other to minimize areas occupied by the first and second TFTs 40 and 60. Moreover, the first TFT 40 includes the first drain electrode 45 facing the first source electrode 43 and connected to the first sub-pixel electrode 150, and the second TFT 60 includes the second drain electrode 65 facing the second source electrode 63 and connected to the second sub-pixel electrode 160. The third TFT 70 includes the third gate electrode 71 formed on the second gate line 13, the third source electrode 73 connected to the first sub-pixel electrode 150, and the third drain electrode 75 facing the third source electrode 73.

The first TFT 40 delivers a gate signal applied from the first gate line 11 to the first sub-pixel electrode 150. The second TFT 60 delivers the gate signal applied from the first gate line 11 to the second sub-pixel electrode 160. In this case, the first and second TFTs 40 and 60 are supplied with the same gate signal. The third TFT 70 delivers a gate signal applied from the second gate line 13 to the first and second sub-pixel electrodes 150 and 160.

Moreover, the first to third TFTs 40, 60 and 70 include first to third semiconductor patterns 50, 55 and 80 forming channels between the first to third source electrodes 43, 63 and 73 and the first to third drain electrodes 45, 65 and 75. The first to third semiconductor patterns 50, 55 and 80 include first to third active layers 51, 57 and 81 forming channels between the first to third source electrodes 43, 63 and 73 and the first to third drain electrodes 45, 65 and 75. Furthermore, the first to third semiconductor patterns 50, 55 and 80 include first to third ohmic contact layers 53, 59 and 83 for ohmic contact between the first to third active layers 51, 57 and 81, the first to third source electrodes 43, 63 and 73, and the first to third drain electrodes 45, 65 and 75.

The passivation layer 110 protects the data line 30 and the first to third TFTs 40, 60 and 70, and has a double-layer structure that includes an inorganic passivation layer 100 and an organic passivation layer 105. The inorganic passivation layer 100 prevents the organic passivation layer 105 from being in contact with the active layers of the first to third TFTs 40, 60 and 70, thus preventing deterioration of characteristics of the first to third TFTs 40, 60 and 70 due to the chemical reaction between the organic passivation layer 105 and the active layers. The organic passivation layer 105 is formed with a permittivity higher than that of the inorganic passivation layer 100 and a thickness greater than that of the inorganic passivation layer 100. As a result, the first and second sub-pixel electrodes 150 and 160 are formed overlapping the gate lines 11 and 13 and the data line 30 without being affected by a capacitor, thus increasing aperture ratios of the first and second sub-pixel electrodes 150 and 160.

Pixel electrodes include the first sub-pixel electrode 150 defining the low gray scale area and the second sub-pixel electrode 160 defining the high gray scale area. The first sub-pixel electrode 150 is connected to the drain electrode 45 of the first TFT 40 via a first contact hole 49 penetrating the passivation layer 110 and, at the same time, connected to the source electrode 73 of the third TFT 70 via a third contact hole 79. The second sub-pixel electrode 160 is connected to the drain electrode 65 of the second TFT 60 via a second contact hole 69 penetrating the passivation layer 110.

The first and second sub-pixel electrodes 150 and 160 are formed in a chevron shape. The area of the first sub-pixel electrode 150 is greater than that of the second sub-pixel electrode 160. For example, the area ratio between the second sub-pixel electrode 160 and the first sub-pixel electrode 150 is preferably set to 1:2 for increased visibility.

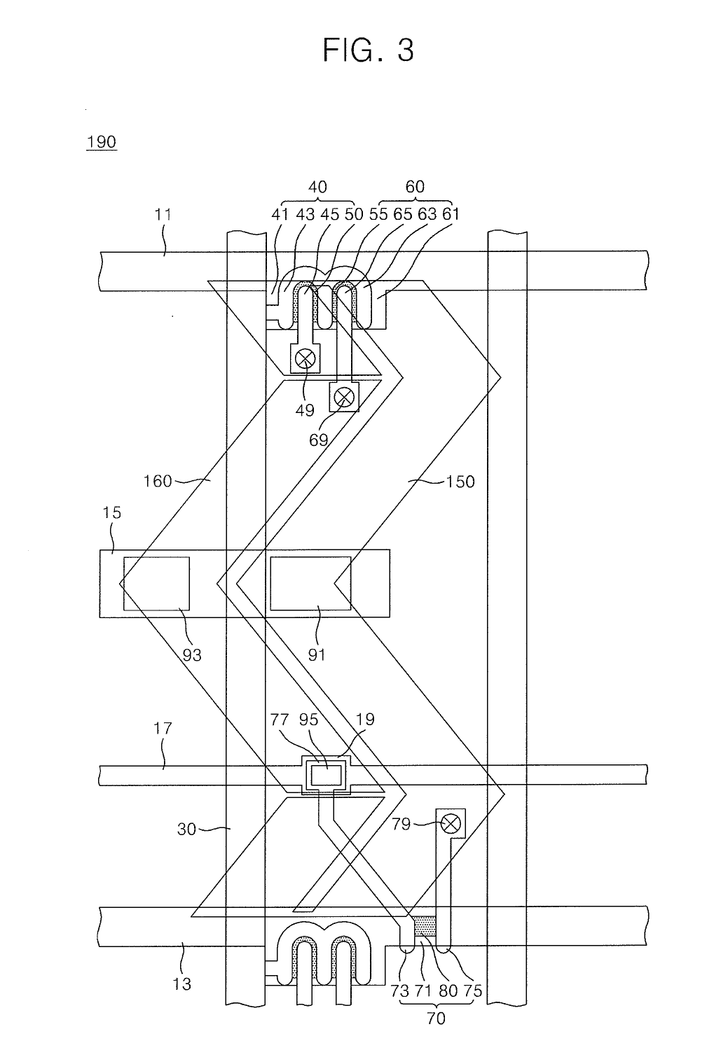

The second sub-pixel electrode 160 is provided to the right of the first sub-pixel electrode 150 and formed in a chevron shape in a short axis direction, for example, based on the first storage line 15. The first sub-pixel electrode 150 is formed in a chevron shape rotated clockwise 90 degrees. For example, the first sub-pixel electrode 150 surrounds the second sub-pixel electrode 160 and is formed in a zigzag shape symmetrical to the first storage line 15. Meanwhile, as shown in FIG. 3, the second sub-pixel electrode 160 is provided next to the left side of the first sub-pixel electrode 150 and surrounded by the first sub-pixel electrode 150.

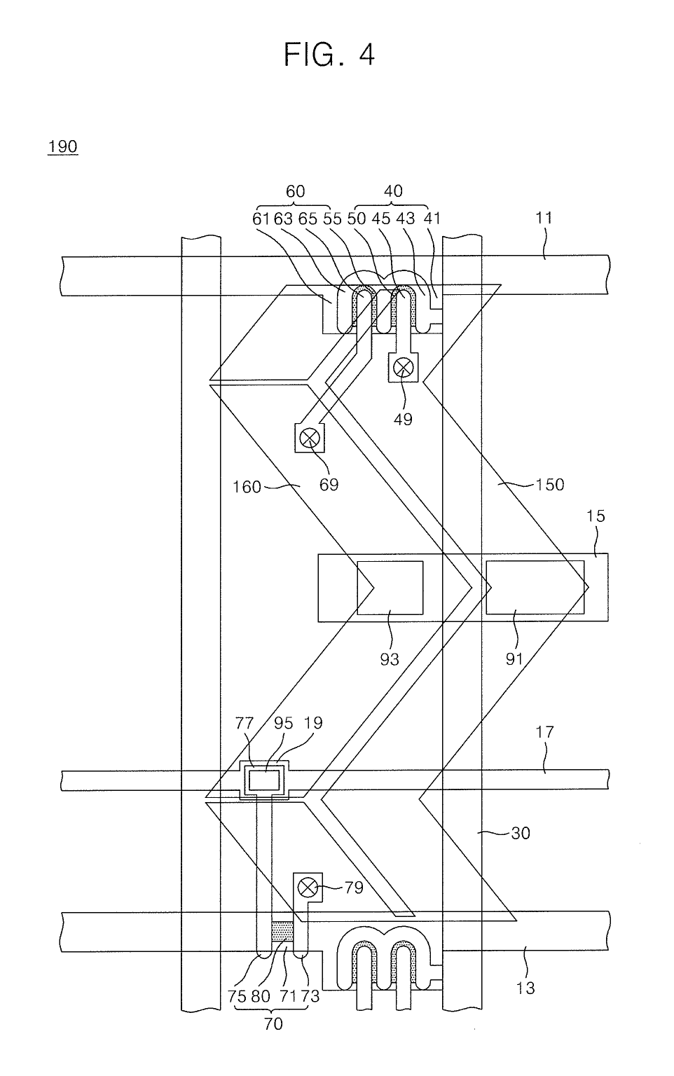

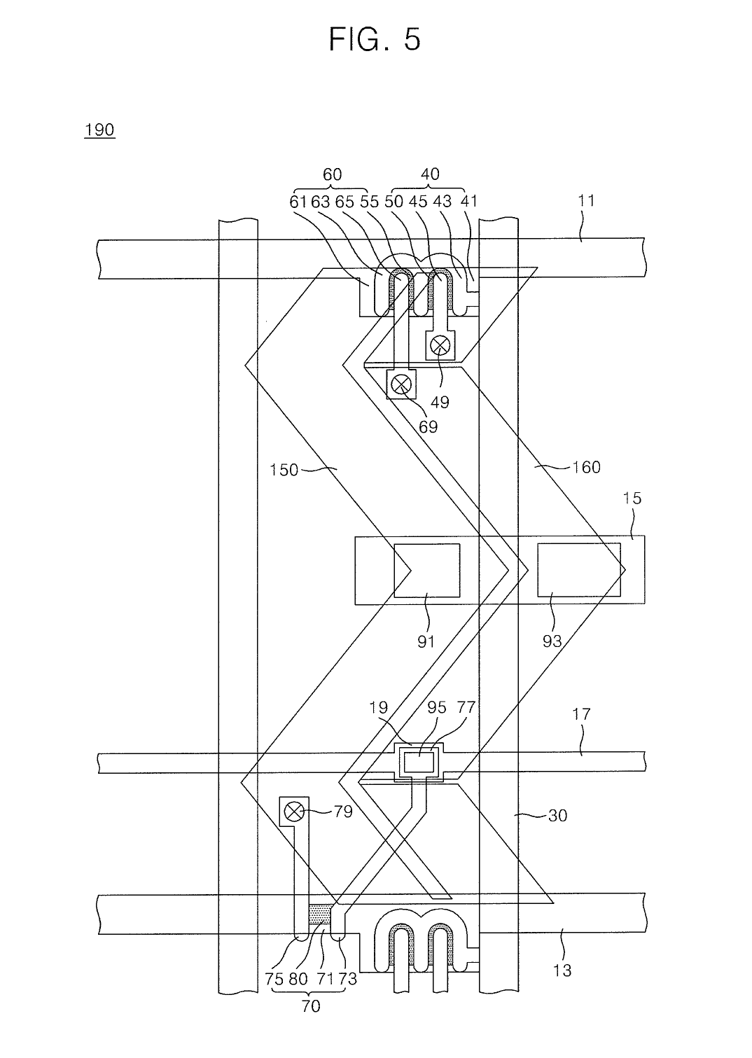

Referring to FIG. 4, the second sub-pixel electrode 160 is provided next to the left side of the first sub-pixel electrode 150 and formed in a chevron shape. The first sub-pixel electrode 150 is formed in a chevron shape rotated counterclockwise 90 degrees. For example, the first sub-pixel electrode 150 surrounds the second sub-pixel electrode 160 and is formed in a zigzag shape symmetrical to the first storage line 15. Meanwhile, as shown in FIG. 5, the second sub-pixel electrode 160 is provided to the right of the first sub-pixel electrode 150 and surrounded by the first sub-pixel electrode 150.

The first sub-pixel electrode 150 overlaps the first storage line 15 to form a first storage capacitor Cst1, and the second sub-pixel electrode 160 overlaps the first storage line 15 to form a second storage capacitor Cst2. Moreover, the second sub-pixel electrode 160 overlaps a coupling electrode 77 to form a voltage variable capacitor Cvc, and the coupling electrode 77 overlaps a storage electrode 19 to form a voltage storage capacitor Cvs.

The first and second storage capacitors Cst1 and Cst2 and the voltage variable capacitor Cvc overlap the inorganic passivation layer 100, while removing the organic passivation layer 105. The first and second storage capacitors Cst1 and Cst2 and the voltage variable capacitor Cvc are provided in capacitor recesses 91, 93 and 95, respectively. For example, the first storage capacitor Cst1 is formed overlapping the first storage line 15 and the first sub-pixel electrode 150 with the gate insulating layer 20 and the inorganic passivation layer 100 interposed therebetween. The second storage capacitor Cst2 is formed overlapping the first storage line 15 and the second sub-pixel electrode 160 with the gate insulating layer 20 and the inorganic passivation layer 100 interposed therebetween. The voltage variable capacitor Cvc is formed overlapping the second sub-pixel electrode 160 and the drain electrode 75 of the third TFT 70 with the inorganic passivation layer 100 interposed therebetween. The voltage storage capacitor Cvs is formed overlapping the second storage line 17 and the drain electrode 75 of the third TFT 70 with the gate insulating layer 20 interposed therebetween.

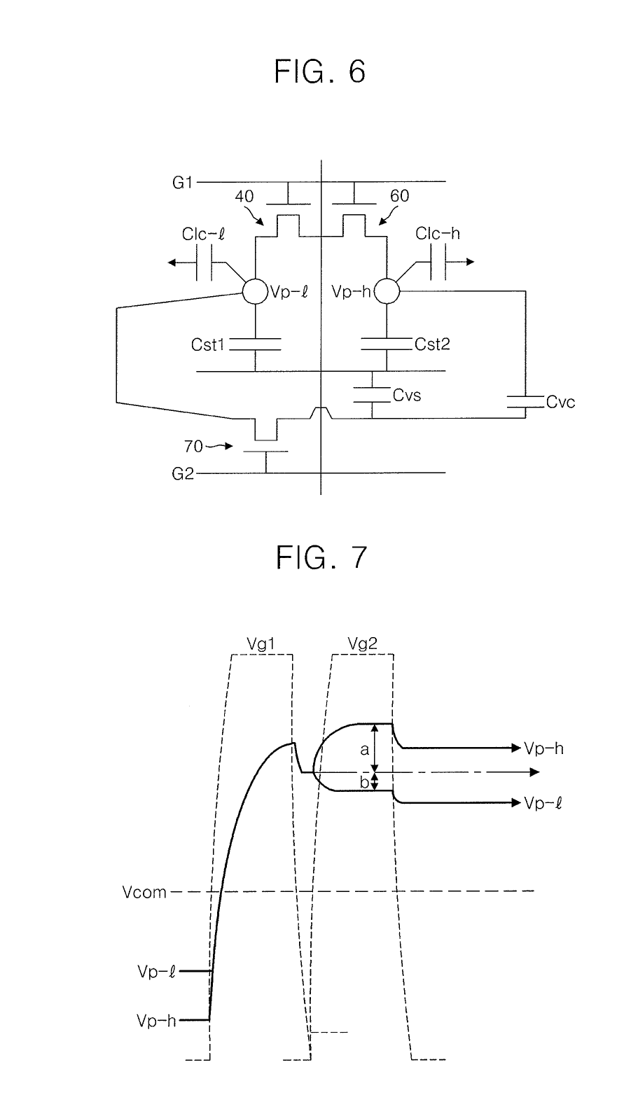

A method of driving the sub-pixel in the TFT substrate 190 will be described with reference to FIGS. 6 and 7 as follows.

First, if a gate signal is applied to the first gate line 11, the first and second TFTs 40 and 60 are activated and thereby a signal voltage of the data line 30 is supplied to the first and second sub-pixel electrodes 150 and 160, respectively. If the gate signal of the first gate line 11 is turned off, a gate signal is applied to the second gate line 13. Accordingly, the TFT substrate 190 is driven by a voltage difference between the first and second sub-pixel electrodes 150 and 160. A description will be given of an example in which a positive voltage (+) is applied as the signal voltage.

If a gate signal is applied via the first gate line 11, the first TFT 40 is activated. Subsequently, a signal voltage of the data line 30 is transmitted to the first sub-pixel electrode 150 via the drain electrode 45 of the first TFT 40. Moreover, the gate signal of the first gate line 11 activates the second TFT 60 at the same time. Accordingly, a liquid crystal capacitor Clc-l, connected to the first TFT 40, and the first storage capacitor Cst1 are charged with a positive voltage (+). Moreover, a liquid crystal capacitor Clc-h, connected to the second TFT 60, and the second storage capacitor Cst2 are charged with the positive voltage (+). Accordingly, the same voltage is applied to the first and second sub-pixel electrodes 150 and 160. Subsequently, low and high gray scale pixel voltages are dropped by a kickback voltage if the gate signal of the first gate line 11 is turned off. The first and second storage capacitors Cst1 and Cst2 charged with the positive voltage (+) are refreshed if the gate signal of the first gate line 11 is turned off, thus being charged with a negative voltage (−).

The third TFT 70 is activated by the gate signal of the second gate line 13. In this case, the charge of the first sub-pixel electrode 150 is refreshed and thereby the voltage storage capacitor Cvs is refreshed with the negative charge (−) via the source electrode 73 and the semiconductor pattern 80 of the third TFT 70. Accordingly, the voltage storage capacitor Cvs is charged with the negative voltage (−) of the first sub-pixel electrode 150. The voltage variable capacitor Cvc connected to the third TFT 70 is charged with a positive voltage (+) to raise the voltage of the second sub-pixel electrode 160 by the voltage a. Although the first storage capacitor Cst1 connected to the third TFT 70 is supplied with the gate signal of the second gate line 13, the voltage of the first sub-pixel electrode 150 is lowered by the refreshed negative voltage b. As a result, a potential difference is generated between the first and second sub-pixel electrodes 150 and 160. Since the second sub-pixel electrode 160 has an increased amount greater than that of the first sub-pixel electrode 150, a voltage higher than the applied voltage is applied thereto. Accordingly, in a case where the S-PVA mode that is a normally black mode has the same aperture ratio, the brightness is further increased. Thereafter, if the gate signal of the second gate line 13 is turned off, the first and second sub-pixel electrodes 150 and 160 generate kickback voltages and thereby the potential state of the first and second sub-pixel electrodes 150 and 160 is sustained until the gate signal of the first gate line 11 is applied.

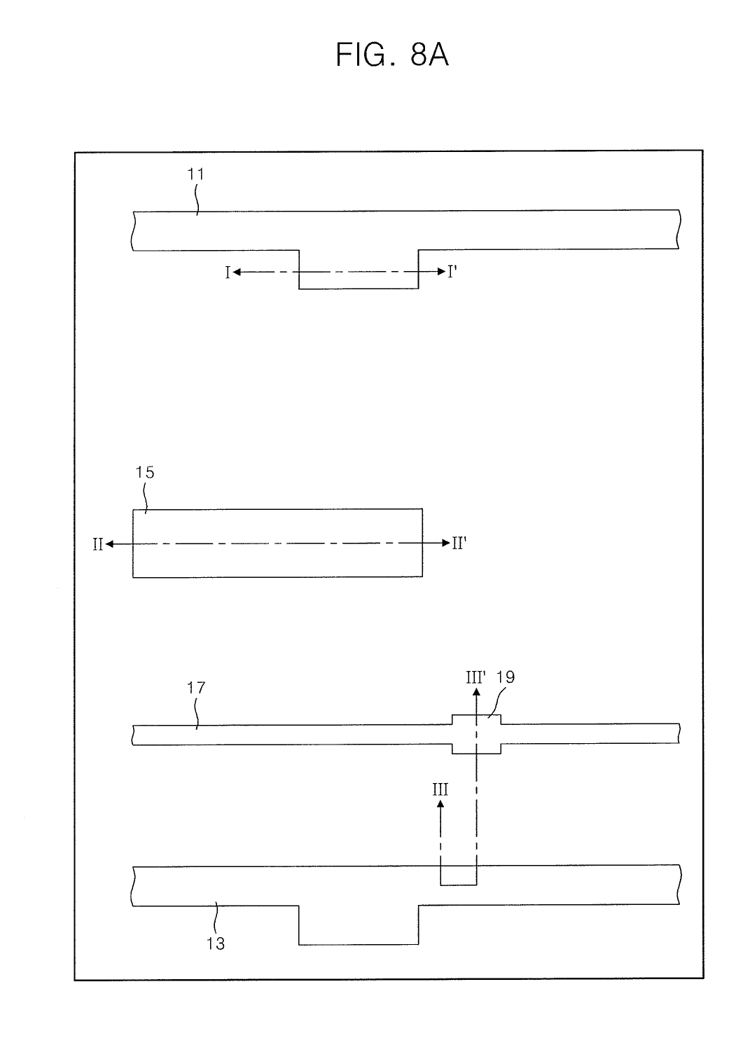

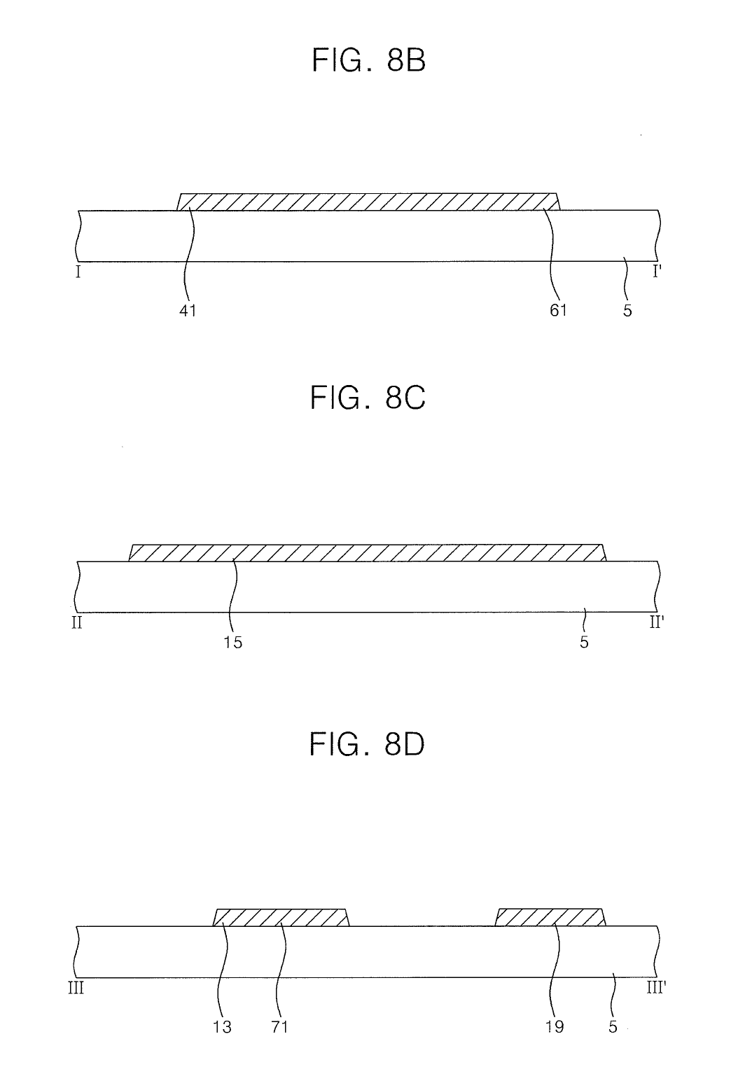

A method of manufacturing a TFT substrate in an LCD according to the present invention will be described in detail with reference to FIGS. 8A to 13D.

FIGS. 8A and 8B to 8D are a plan view and cross-sectional views, respectively, illustrating a first mask process in a method of manufacturing a TFT substrate according to an exemplary embodiment of the present invention.

Referring to FIGS. 8A to 8D, first and second gate lines 11 and 13, and first to third gate electrodes 41, 61 and 71 connected to the first and second gate lines 11 and 13 are formed on an insulating substrate 5 by a first mask process. A gate metal pattern including a storage electrode 19, formed parallel to the gate lines 11 and 13, and first and second storage lines 15 and 17 are formed. For example, a gate metal layer is formed on the insulating substrate 5 using a deposition process such as sputtering. The gate metal layer comprises molybdenum (Mo), aluminum (Al), chromium (Cr), and an alloy thereof stacked in a single or double layer. Subsequently, the gate metal layer is patterned by photolithography and etching processes using a first mask to form a gate metal pattern including the first and second gate lines 11 and 13, the first to third gate electrodes 41, 61 and 71, the first and second storage lines 15 and 17, and the storage electrode 19.

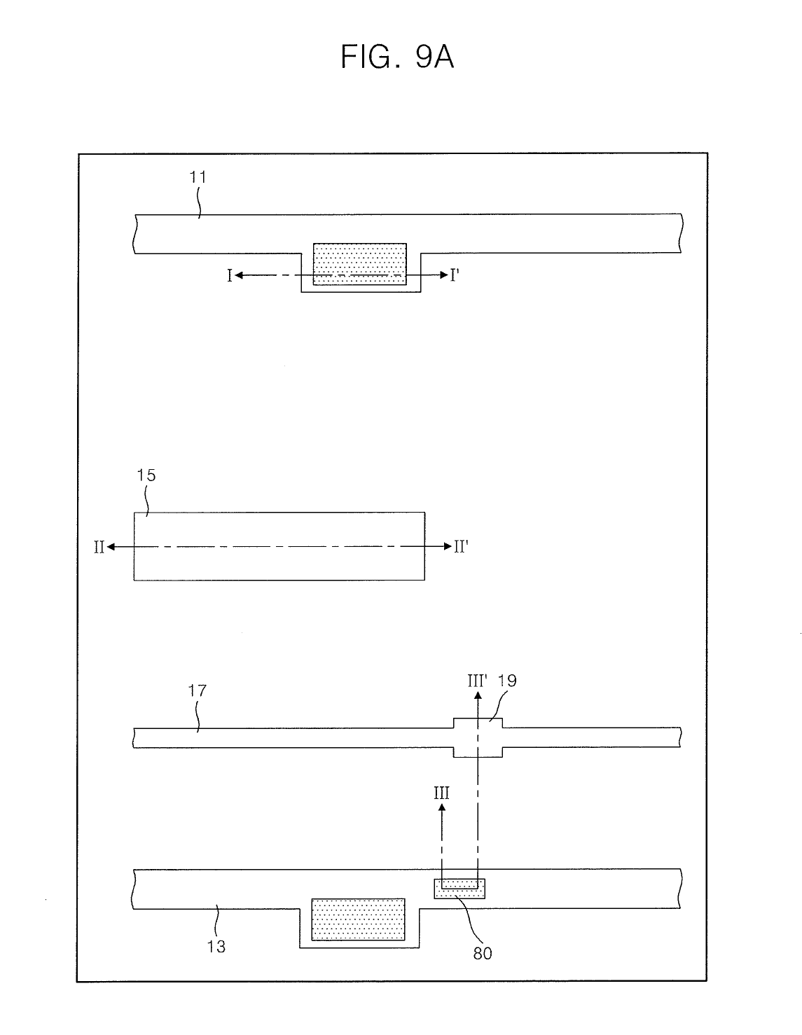

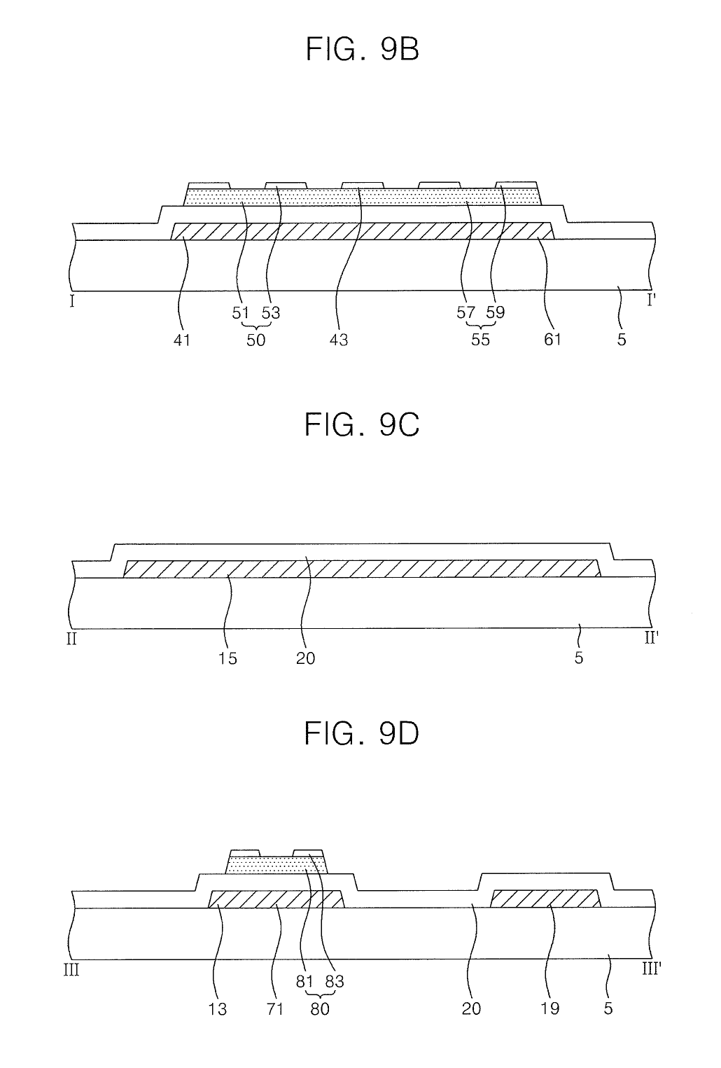

FIGS. 9A and 9B to 9D are a plan view and cross-sectional views, respectively, illustrating a second mask process in the method of manufacturing the TFT substrate according to an exemplary embodiment of the present invention.

Referring to FIGS. 9A to 9D, a gate insulating layer 20 is formed on the insulating substrate 5 on which the gate metal pattern is formed. Subsequently, semiconductor patterns 50, 55 and 80 including active layers 51, 57 and 81 and ohmic contact layers 53, 59 and 83 are formed overlapping a portion of the first and second gate lines 11 and 13 and the first to third gate electrodes 41, 61 and 71 on the gate insulating layer 20 by a second mask process. For example, the gate insulating layer 20, an amorphous silicon layer and an n+ amorphous silicon layer are sequentially formed on the insulating layer 5, on which the gate metal pattern is formed, using a deposition process such as PECVD. Then, the n+ amorphous silicon layer and the amorphous silicon layer are patterned by photolithography and etching processes using a second mask to form the semiconductor patterns 50, 55 and 80 including the active layers 51, 57 and 81 and the ohmic contact layers 53, 59 and 83. In this case, the gate insulating layer 20 is formed of an inorganic insulating material such as silicon oxide (SiOₓ), silicon nitride (SiNₓ), and the like.

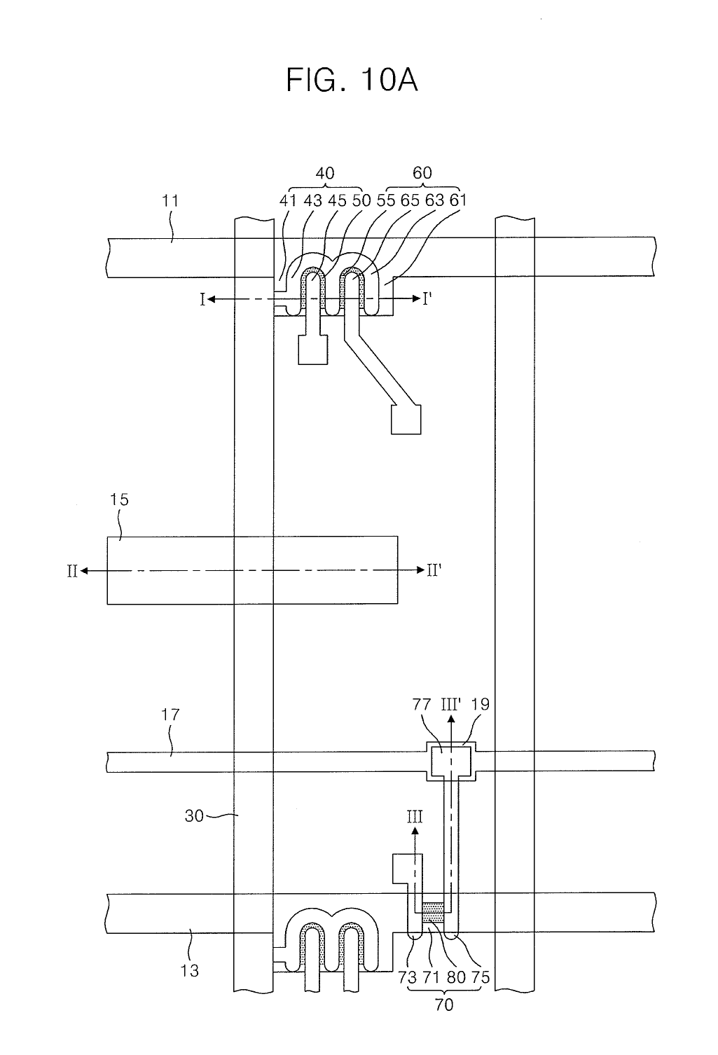

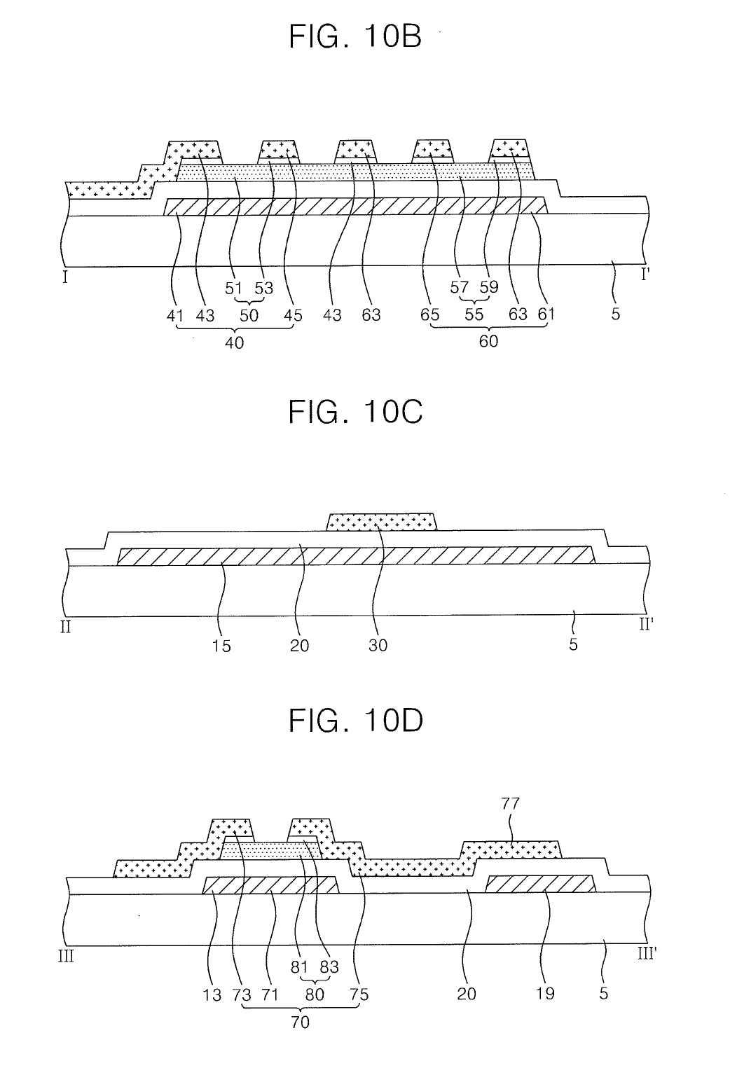

FIGS. 10A and 10B to 10D are a plan view and cross-sectional views, respectively, illustrating a third mask process in a method of manufacturing a TFT substrate according to an exemplary embodiment of the present invention.

Referring to FIGS. 10A to 10D, a source/drain metal pattern including a data line 30, source electrodes 43, 63 and 73, drain electrodes 45, 65 and 75, and a coupling electrode 77 are formed on the gate insulating layer 20, on which the semiconductor patterns 50, 55 and 80 are formed, by a third mask process. For example, the source/drain metal layer is formed on the gate insulating layer 20, on which the semiconductor patterns 50, 55 and 80 are formed, using a sputtering process. Subsequently, the source/drain metal layer is patterned by photolithography and etching processes using a third mask to form the source/drain metal pattern including the data line 30, the source electrodes 43, 63 and 73, the drain electrodes 45, 65 and 75, and the coupling electrode 77. Then, the ohmic contact layers 53, 59 and 83 exposed between the source electrodes 43, 63 and 73 and the drain electrodes 45, 65 and 75 are removed to form first and second TFTs 40 and 60 connected to the first gate line 11 and the data line 30. Specifically, the source electrodes 43 and 63 of the first and second TFTs 40 and 60 are formed partially overlapping each other. Then, a third TFT 70 is formed on the second gate line 13. In this case, the semiconductor patterns 50, 55 and 80 and the source/drain metal pattern may be formed by a single mask process using a diffractive exposure mask or a half-tone mask.

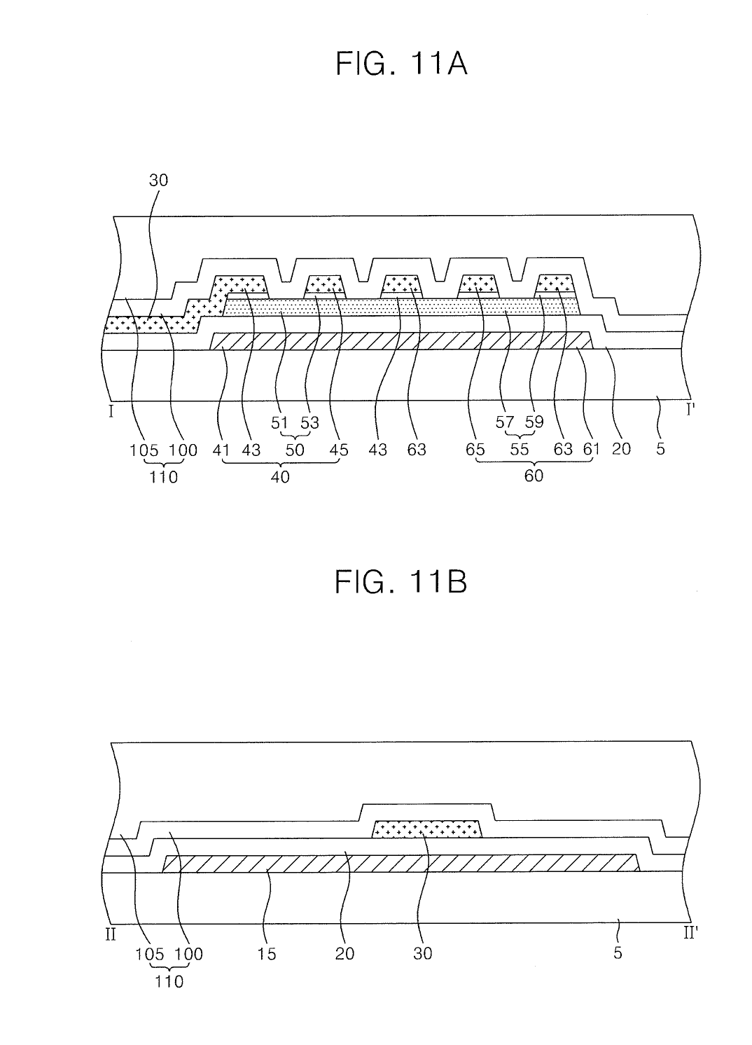

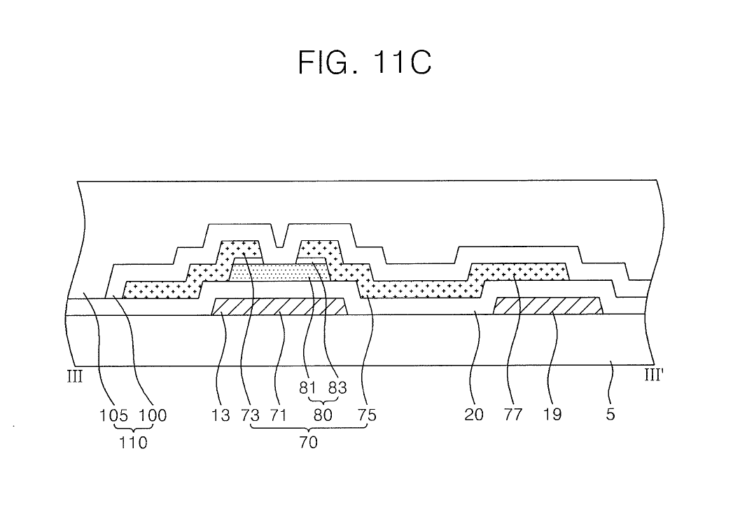

FIGS. 11A to 11C are cross-sectional views illustrating a process of forming a passivation layer in the method of manufacturing the TFT substrate according to an exemplary embodiment of the present invention.

Referring to FIGS. 11A to 11C, an inorganic passivation layer 100 and an organic passivation layer 105 are formed on the gate insulating layer 20 on which the source/drain metal pattern is formed. For example, the inorganic passivation layer 100 is formed on the gate insulating layer 20, on which the source/drain metal pattern is formed, using a deposition process such as PECVD. The organic passivation layer 105 is formed on the inorganic passivation layer 100 using a spin coating process, a spinless coating process, or the like. In this case, the inorganic passivation layer 100 is formed of the same inorganic insulating material as the gate insulating layer 20, and the organic passivation layer 105 is formed of an acryl organic compound or an organic insulating material such as BCB, PFCB, and the like.

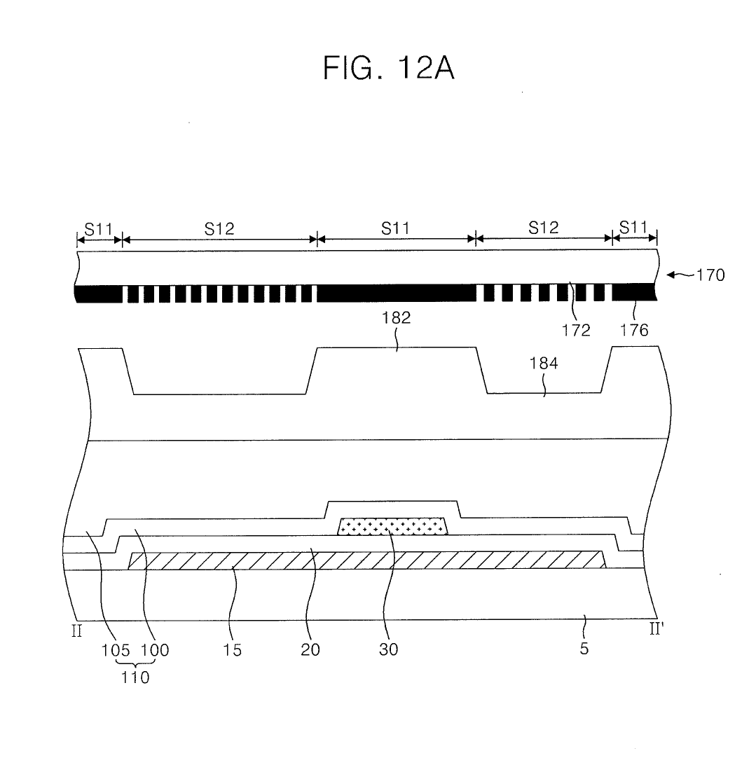

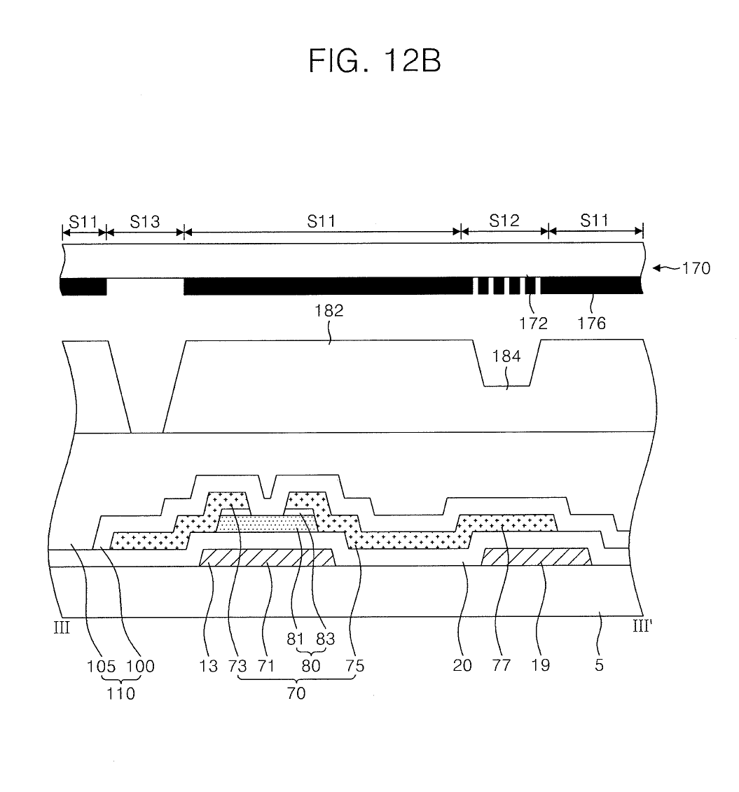

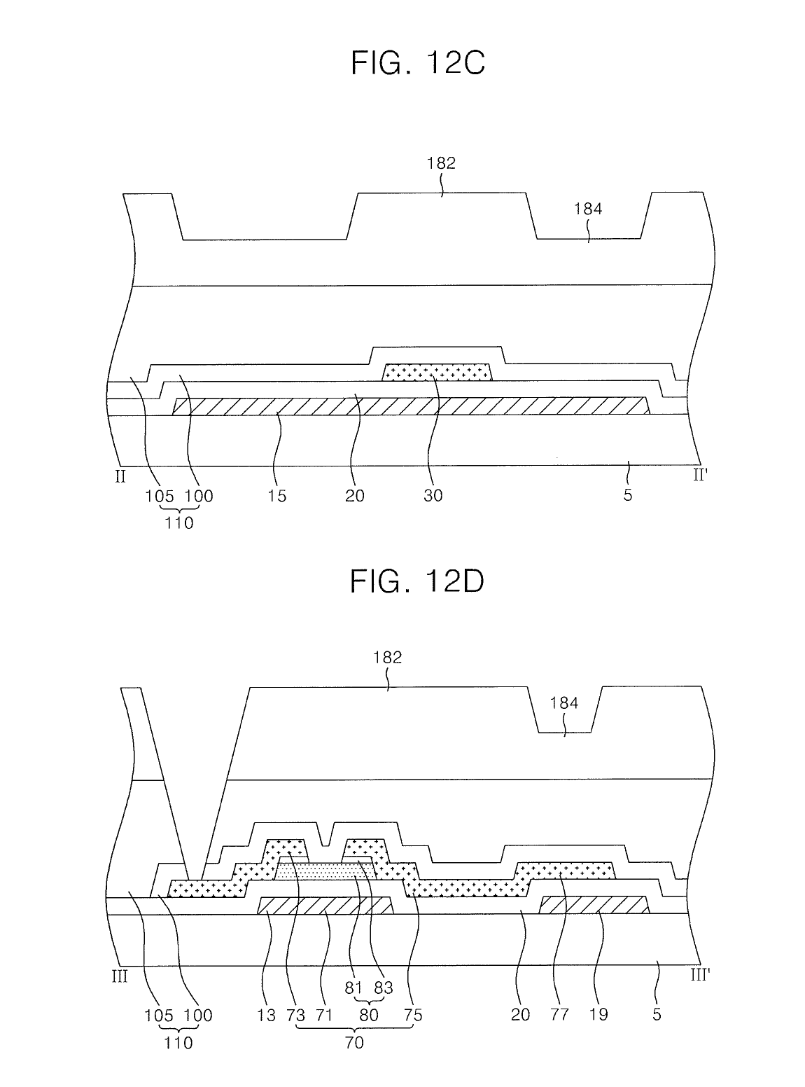

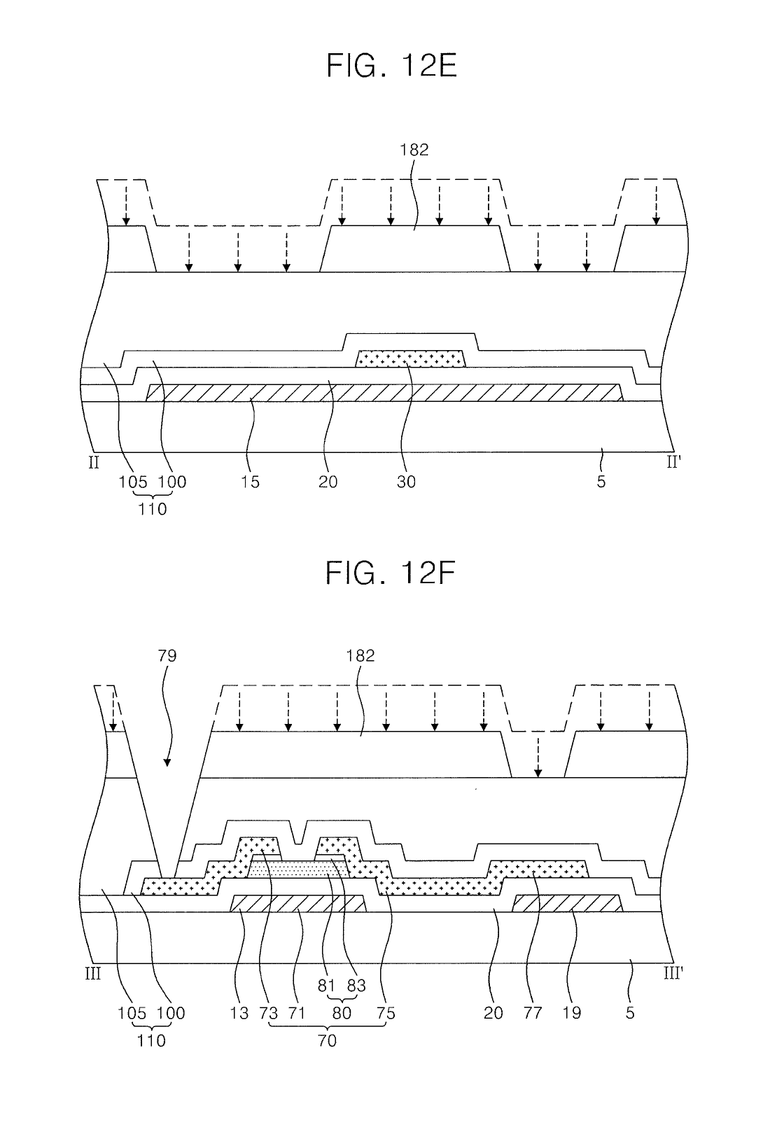

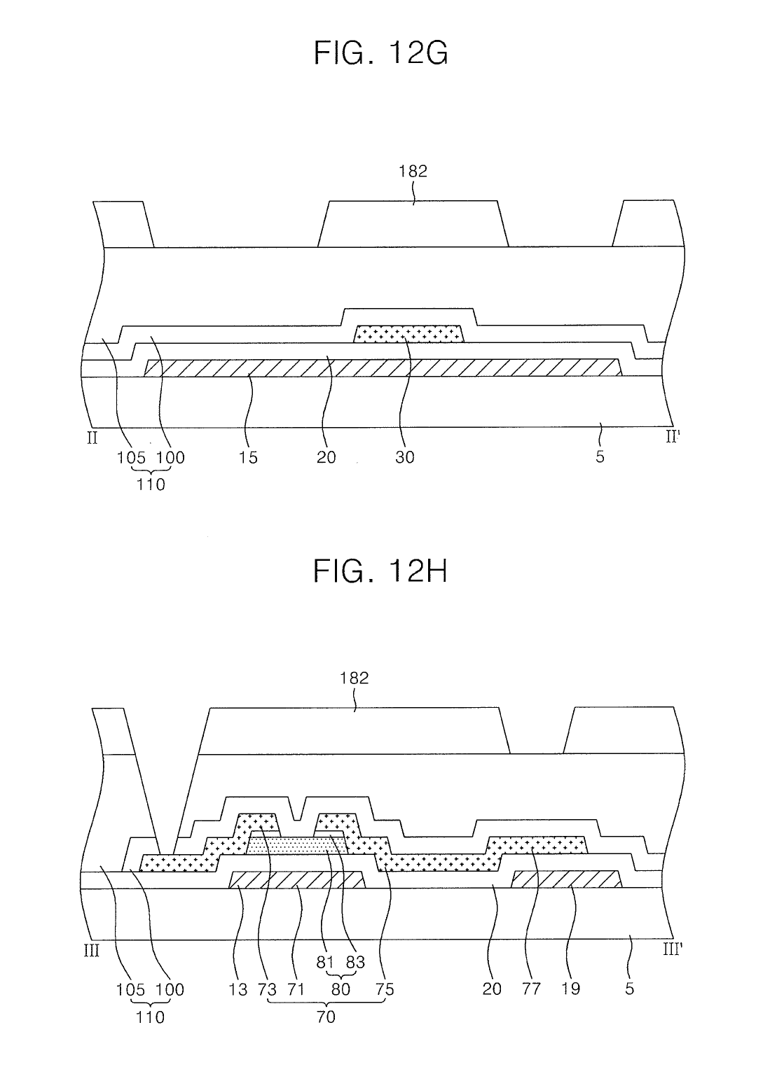

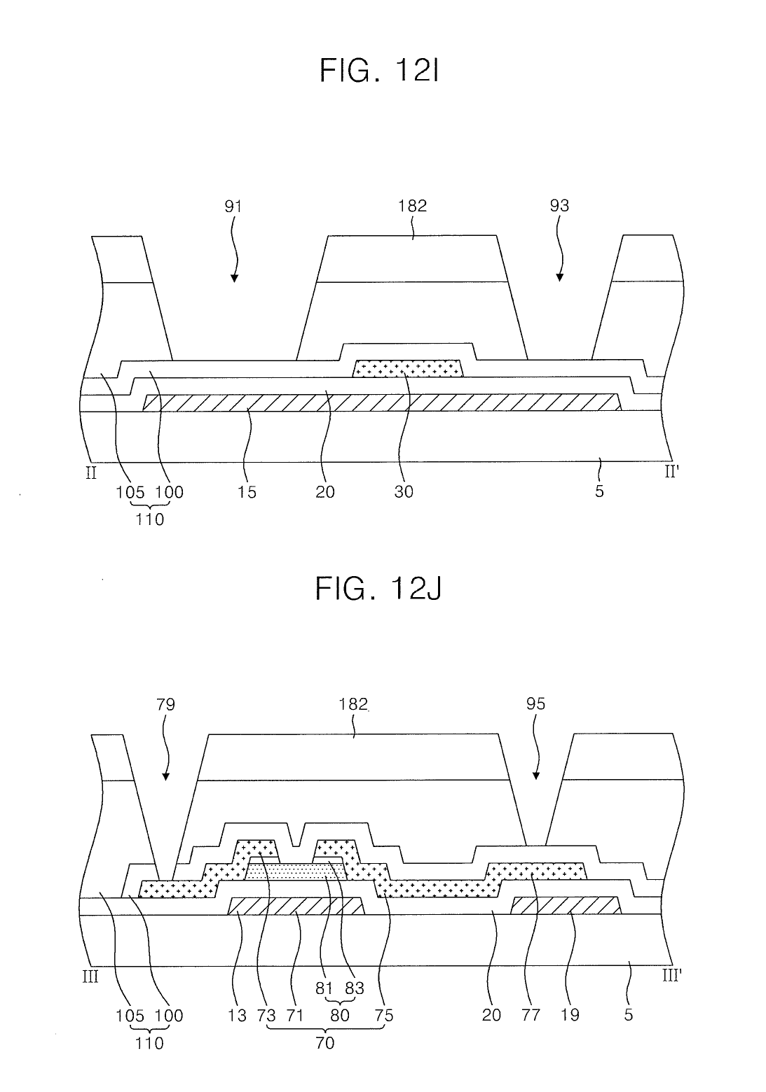

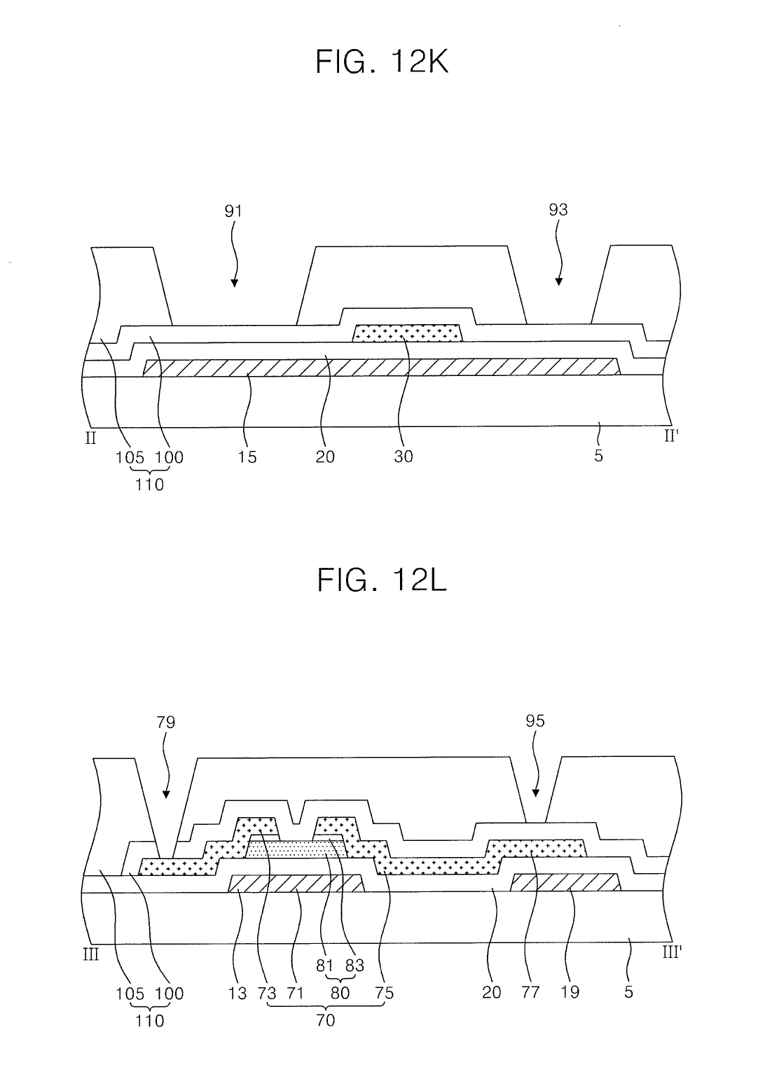

FIGS. 12A to 12L are cross-sectional views illustrating processes of forming contact holes and capacitor recesses in a method of manufacturing the TFT substrate according to an exemplary embodiment of the present invention.

Referring to FIGS. 12A and 12B, after photoresist is applied on the organic passivation layer 105, the photoresist is exposed and developed by a photography process using a semi-transparent mask or a slit mask 170 to form first and second photoresist patterns 182 and 184 having a thickness different from each other. For example, the slit mask 170 includes a barrier area S11 having a barrier layer 176 formed on a quartz substrate 172, a slit area S12 having a plurality of slits formed on the quartz substrate 172, and a transmission area S13 including the quartz substrate 172 only. The barrier area S11 cuts off UV-rays during an exposure process and thereby the first photoresist pattern 182 is left after a development process, as shown in FIGS. 12E and 12F. The slit area S12 is positioned at an area, in which capacitor recesses 91, 93 and 95 are to be formed, to diffract UV-rays during the exposure process and thereby the first photoresist pattern 182 having a thickness greater than that of the second photoresist pattern 184 is left after the development process, as shown in FIGS. 12G and 12H. The transmission area S13 is positioned at an area, in which contract holes 49, 69 and 79 are to be formed, to transmit UV-rays, thus removing the photoresist after the development process.

Referring to FIGS. 12C and 12D, the organic and inorganic passivation layers 105 and 100 are removed from the transmission area S13 by being patterned by a first etching process using the first and second photoresist patterns 182 and 184 as a mask. Subsequently, as shown in FIGS. 12E and 12F, an etching process using oxygen (O₂) plasma is carried out to reduce the thickness of the first photoresist pattern 182 and remove the second photoresist pattern 184. Then, as shown in FIGS. 12G and 12H, only the photoresist pattern 182 remains. Next, as shown in FIGS. 12I and 12J, the exposed organic passivation layer 105 is removed by a second etching process using the etched first photoresist pattern 182 as a mask. Lastly, as shown in FIGS. 12K and 12L, the first photoresist pattern 182 is removed from the organic passivation layer 105 by a stripping process.

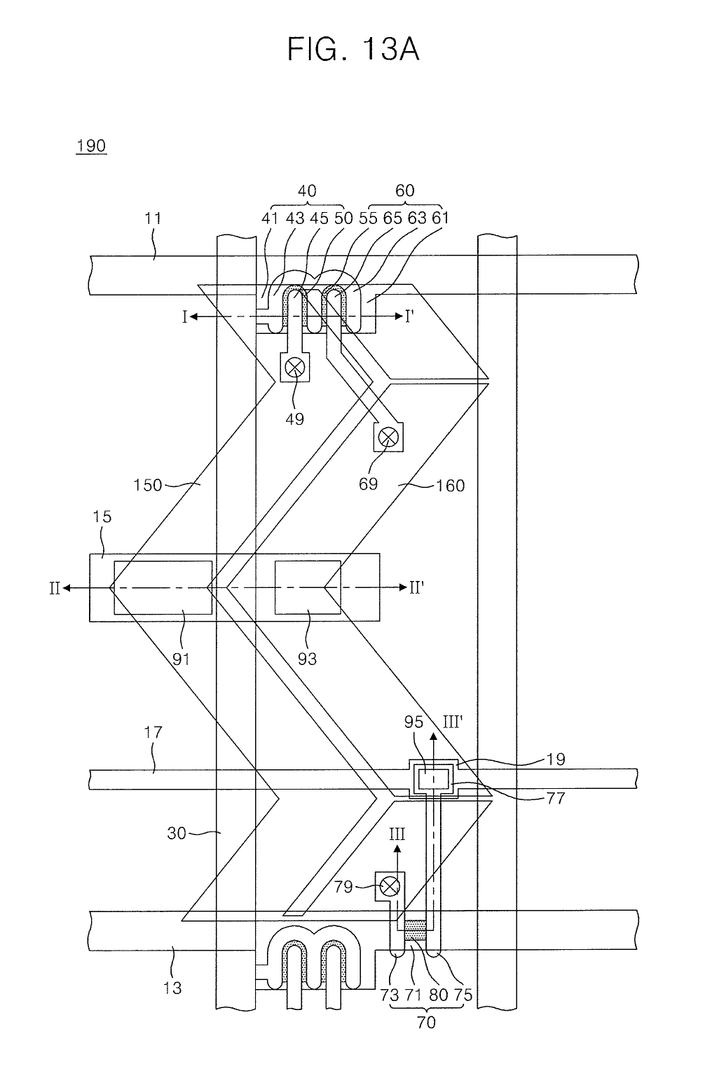

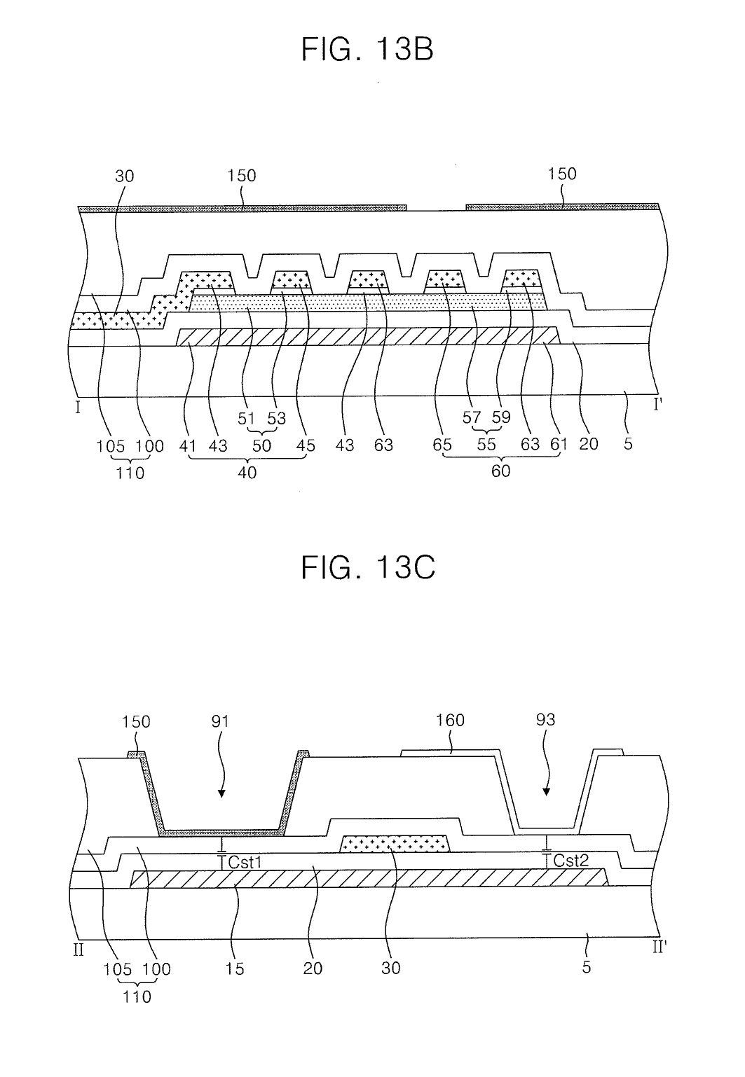

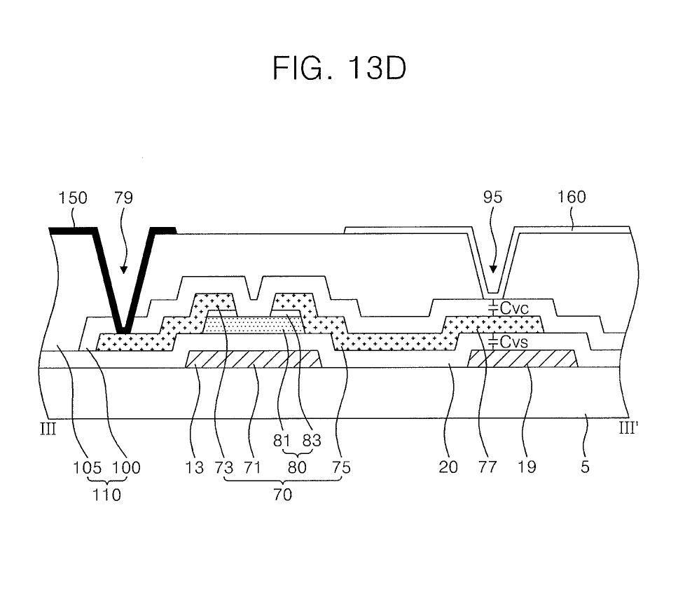

FIGS. 13A and 13B through 13D are a plan view and cross-sectional views illustrating a fifth mask process in a method of manufacturing the TFT substrate according to an exemplary embodiment of the present invention.

Referring to FIGS. 13A and 13B through 13D, a transparent conductive pattern including first and second sub-pixel electrodes 150 and 160 is formed on the organic passivation layer 105 by a fifth mask process. For example, the first and second sub-pixel electrodes 150 and 160 are formed by applying a transparent conductive material such as indium tin oxide (ITO), tin oxide (TO), indium zinc oxide (IZO), ITZO, and the like on the organic passivation layer 105 and then pattering the transparent conductive material by photolithography and etching processes using a fifth mask. In this case, the first sub-pixel electrode 150 is connected to the drain electrode 45 of the first TFT 40 via the first contact hole 49 and is also connected to the source electrode 73 of the third TFT 70 via the third contact hole 79. The second sub-pixel electrode 160 is connected to the drain electrode 65 of the second TFT 60 via the second contact hole 69.

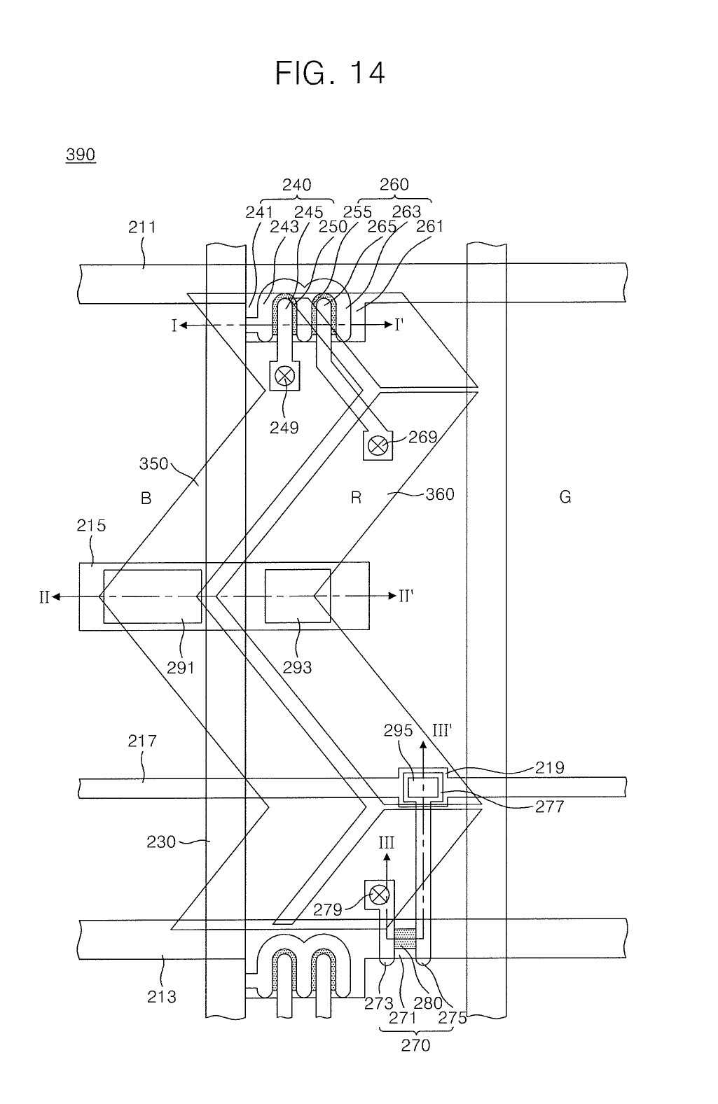

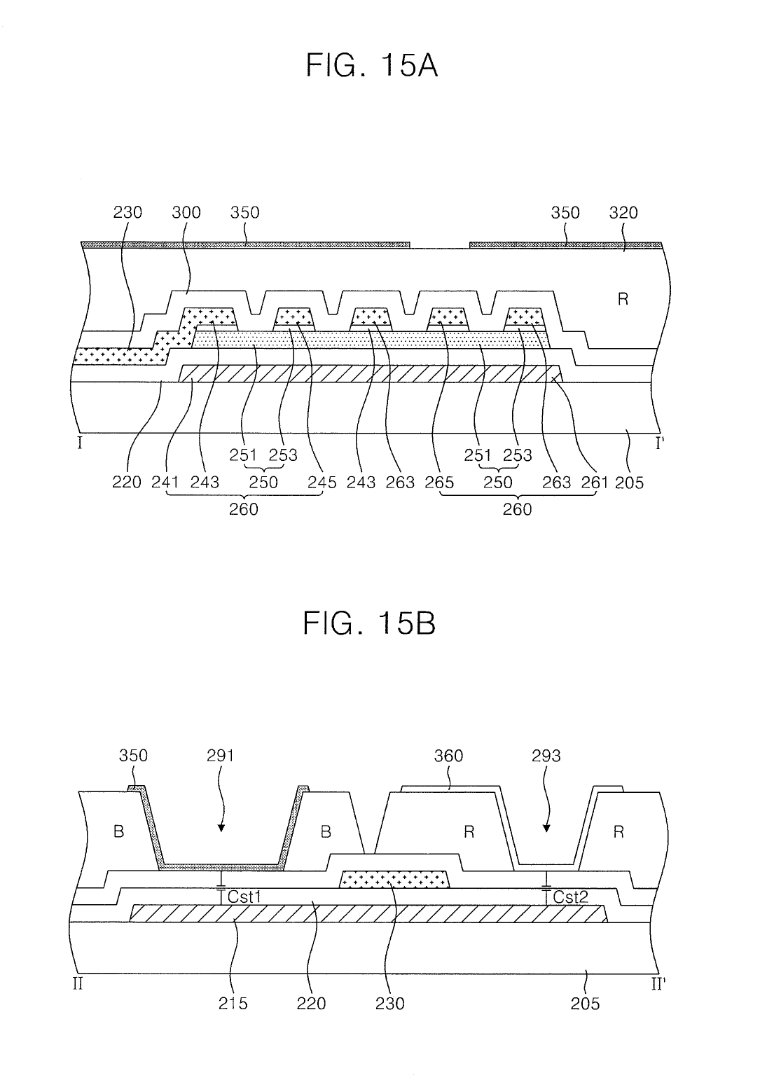

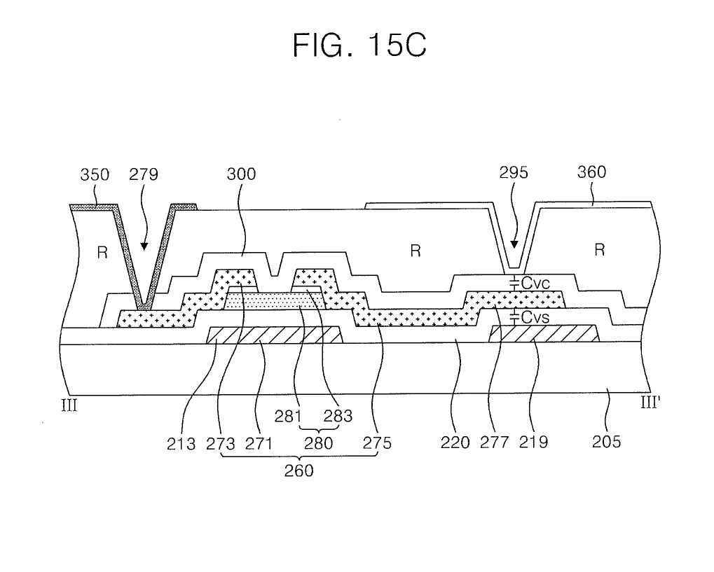

FIG. 14 is a plan view of a TFT substrate according to an exemplary embodiment of the present invention, and FIGS. 15A to 15C are cross-sectional views of the TFT substrate according to an exemplary embodiment of the present invention.

Since a TFT substrate 390 shown in FIGS. 14 and 15A to 15C includes the same elements as the former TFT substrate shown in FIGS. 2A to 2C and 3 except that the organic passivation layer 105 is replaced by color filters 320, a brief description will be given as follows.

Referring to FIGS. 14 and 15A to 15C, a sub-pixel of the TFT substrate 390 includes first and second gate lines 211 and 213, a data line 230 intersecting the first and second gate lines 211 and 213, and a gate insulating layer 220 interposed therebetween. The first and second gate lines 211 and 213 and the data line 230 define a sub-pixel area in which first and second sub-pixel electrodes 350 and 360 are formed. First and second TFTs 240 and 260 are formed at an intersection between the first gate line 211 and the data line 230. Moreover, a third TFT 270 is formed on the second gate line 213. The first and second TFTs 240 and 260 include first and second gate electrodes 241 and 261, protruding to the first gate line 211, and source electrodes 243 and 263 connected to the data line 230, respectively. The first and second source electrodes 243 and 263 are formed overlapping each other to minimize areas occupied by the first and second TFTs 240 and 260. Moreover, the first TFT 240 includes a first drain electrode 245 facing the source electrode 243 and connected to the first sub-pixel electrode 350, and the second TFT 260 includes a second drain electrode 265 connected to the second sub-pixel electrode 360. The third TFT 270 includes a third gate electrode 271 connected to the second gate line 213, a source electrode 273 connected to the first sub-pixel electrode 350, and a third drain electrode 275 facing the source electrode 273. The first to third TFTs 240, 260 and 270 include active layers 251, 257 and 281 overlapping the first to third gate electrodes 241, 261 and 271 with the gate insulating layer 220 interposed therebetween and forming channels between the source electrodes 243, 263 and 273 and the drain electrodes 245, 265 and 275, and ohmic contact layers 253, 259 and 283 formed on the active layers 251, 257 and 281, except for the channel areas thereof, for ohmic contact between the source electrodes 243, 263 and 273 and the drain electrodes 245, 265 and 275, respectively.

An inorganic passivation layer 300 is formed to protect the data line 230 and the first to third TFTs 240, 260 and 270. Each of R, G and B color filters 320 is formed in a corresponding sub-pixel area on the inorganic passivation layer 300. Since the color filters 320 comprise photoresist or color resin mixed with R, G and B pigments, the color filters 320 also play a role as the organic passivation layer 305 described above. Each of the R, G and B color filters 320 is formed with a dot shape in the unit of a sub-pixel or with a stripe shape in the unit of a column line.

Pixel electrodes include the first sub-pixel electrode 350 defining a low gray scale area and the second sub-pixel electrode 360 defining a high gray scale area. The pixel electrodes are formed in the unit of a sub-pixel on the R, G and B color filters 320. The first sub-pixel electrode 350 is connected to the first drain electrode 245 via a first contact hole 249 penetrating the color filter 320 and the inorganic passivation layer 300 and, at the same time, connected to the third source electrode 275 via a third contact hole 279. The second sub-pixel electrode 360 is connected to the second drain electrode 265 via a second contact hole 269 penetrating the color filter 320 and the inorganic passivation layer 300. The first and second sub-pixel electrodes 350 and 360 overlap a first storage line 215 parallel to the gate lines 211 and 213 with the gate insulating layer 220 and the inorganic passivation layer 300 interposed therebetween to form first and second capacitors Cst1 and Cst2, respectively. The second sub-pixel electrode 360 includes a voltage variable capacitor Cvc formed overlapping a coupling electrode 277 with the inorganic passivation layer 300 interposed therebetween. Moreover, the coupling electrode 277 includes a voltage storage capacitor Cvs formed overlapping the storage electrode 219 with the gate insulating layer 220 interposed therebetween.

As described above, the TFT substrate in accordance with exemplary embodiments of the present invention includes an additional TFT, a voltage storage capacitor and a coupling electrode to drive the S-PVA mode, thus simplifying the structure thereof. Moreover, exemplary embodiments of the present invention reduces the manufacturing cost of the data driver and improves the aperture ratio. Furthermore, since a potential difference between first and second sub-pixel electrodes is generated to apply a voltage higher than that applied to a TFT substrate, the present invention implements a brighter pixel area with the same aperture ratio.

It will be apparent to those skilled in the art that various modifications and variations can be made in the present invention without departing from the spirit or scope of the inventions.

What is claimed is:

1. A thin film transistor substrate comprising:
a first gate line, a second gate line, and a data line;
a first sub-pixel electrode and a second sub-pixel electrode;
a first thin film transistor having three terminals connected to the first gate line, the data line, and the first sub-pixel electrode, respectively;
a second thin film transistor having three terminals connected to the first gate line, the data line, and the second sub-pixel electrode, respectively;
a coupling electrode overlapping the second sub-pixel electrode with a passivation layer interposed therebetween; and
a third thin film transistor having three terminals connected to the second gate line, the second sub-pixel electrode, and the coupling electrode, respectively.

2. The thin film transistor substrate of claim 1, wherein the passivation layer comprises:
an inorganic passivation layer comprising an inorganic material; and
an organic passivation layer comprising an organic material on the inorganic passivation layer.

3. The thin film transistor substrate of claim 2, wherein the third thin film transistor comprises:
a gate electrode connected to the second gate line;
a source electrode connected to the first sub-pixel electrode;
a drain electrode facing the source electrode; and
a semiconductor layer connected to the source electrode and the drain electrode.

4. The thin film transistor substrate of claim 3, wherein the third thin film transistor is on the second gate line.

5. The thin film transistor substrate of claim 3, wherein the first and second sub-pixel electrodes are in a chevron shape.

6. The thin film transistor substrate of claim 5, wherein the first sub-pixel electrode has a greater area than the second sub-pixel electrode.

7. The thin film transistor substrate of claim 6, wherein the first sub-pixel electrode has twice the area of the second sub-pixel electrode.

8. The thin film transistor substrate of claim 3, further comprising a first storage line overlapping the first and second sub-pixel electrodes.

9. The thin film transistor substrate of claim 8, further comprising:
a first storage capacitor overlapping the first storage line and the first sub-pixel electrode with the inorganic passivation layer interposed therebetween; and
a second storage capacitor overlapping the first storage line and the second sub-pixel electrode with the inorganic passivation layer interposed therebetween.

10. The thin film transistor substrate of claim 3, further comprising a second storage line overlapping the coupling electrode.

11. The thin film transistor substrate of claim 10, further comprising a storage electrode overlapping the coupling electrode with a gate insulating layer interposed therebetween.

12. The thin film transistor substrate of claim 3, wherein a source electrode of the first thin film transistor is partially overlapping a source electrode of the second thin film transistor.

13. A method of manufacturing a thin film transistor substrate, comprising:
forming a gate metal pattern including a gate line, a gate electrode, and a storage line, on a substrate;
forming a gate insulating layer and a semiconductor pattern on the gate metal pattern;
forming a data metal pattern including a data line, a source electrode, and a drain electrode on the gate insulating layer on which the semiconductor pattern is formed;
forming a passivation layer on the gate insulating layer and the data metal pattern;
forming contact holes exposing the gate metal pattern and the data metal pattern by removing the passivation layer, and forming capacitor recesses by removing a portion of the passivation layer; and
forming first and second sub-pixel electrodes on the passivation layer, the contact holes, and the capacitor recesses.

14. The method of claim 13, wherein forming the passivation layer comprises:
forming an inorganic passivation layer comprising inorganic material on the gate insulating layer and the data metal pattern; and
forming an organic passivation layer comprising organic material on the inorganic passivation layer.

15. The method of claim 14, wherein forming the contact holes and the capacitor recesses comprises:
forming a photoresist pattern, including an open area from which the photoresist pattern is removed and an intermediate area from which a portion of the photoresist pattern is removed, on the organic passivation layer;
forming the contact holes by removing portions of the organic and inorganic passivation layers through the open area of the photoresist pattern;
removing the photoresist pattern of an exposed area of the photoresist pattern;
forming the capacitor recesses by removing portions of the organic passivation layer through the exposed area of the photoresist pattern; and
removing the photoresist pattern.

16. The method of claim 15, wherein a slit mask is used in forming the contact holes and the capacitor recesses.

17. The method of claim 15, wherein a half-tone mask is used in forming the contact holes and the capacitor recesses.

18. A thin film transistor substrate comprising:
a first gate line, a second gate line, and a data line;
a first sub-pixel electrode and a second sub-pixel electrode;
a first thin film transistor having three terminals connected to the first gate line, the data line, and the first sub-pixel electrode, respectively;
a second thin film transistor having three terminals connected to the first gate line, the data line, and the second sub-pixel electrode, respectively;
a passivation layer covering the data line, the first and second thin film transistors, and a third thin film transistor;
a color filter on the passivation layer;
a coupling electrode overlapping the second sub-pixel electrode with the passivation layer interposed therebetween; and
the third thin film transistor having three terminals connected to the second gate line, the second sub-pixel electrode, and the coupling electrode, respectively.

19. The thin film transistor substrate of claim 18, wherein the passivation layer is an inorganic passivation layer comprising an inorganic material.

20. The thin film transistor substrate of claim 19, wherein the third thin film transistor comprises:
a gate electrode connected to the second gate line;
a source electrode connected to the first sub-pixel electrode;
a drain electrode facing the source electrode; and
a semiconductor layer connected to the source and drain electrodes.

21. The thin film transistor substrate of claim 20, wherein the third thin film transistor is formed on the second gate line.

22. The thin film transistor substrate of claim 20, wherein the first and second sub-pixel electrodes are in a chevron shape.

23. The thin film transistor substrate of claim 22, wherein the first sub-pixel electrode has a greater area than the second sub-pixel electrode.

24. The thin film transistor substrate of claim 23, wherein the first sub-pixel electrode has twice the area of the second sub-pixel electrode.

25. The thin film transistor substrate of claim 20, further comprising a first storage line overlapping the first and second sub-pixel electrodes.

26. The thin film transistor substrate of claim 25, further comprising:
a first storage capacitor overlapping the first storage line and the first sub-pixel electrode with the inorganic passivation layer interposed therebetween; and
a second storage capacitor overlapping the first storage line and the second sub-pixel electrode with the inorganic passivation layer interposed therebetween.

27. The thin film transistor substrate of claim 20, further comprising a second storage line overlapping the coupling electrode.

28. The thin film transistor substrate of claim 27, further comprising a storage electrode overlapping the coupling electrode with a gate insulating layer interposed therebetween.

29. The thin film transistor substrate of claim 20, wherein a source electrode of the first thin film transistor partially overlaps a source electrode of the second thin film transistor in part.
